(19) United States
(12) Patent Application Publication
(10) Pub. No.: US 2026/0121003 A1
(43) Pub. Date: Apr. 30, 2026

(54) STAGE AND PLASMA PROCESSING APPARATUS

(71) Applicant: Tokyo Electron Limited, Tokyo (JP)

(72) Inventors: Kentaro FUJII, Miyagi (JP); Wataru SHIMIZU, Miyagi (JP); Gaku SHIMODA, Miyagi (JP)

(73) Assignee: Tokyo Electron Limited, Tokyo (JP)

(21) Appl. No.: 19/433,130

(22) Filed: Dec. 26, 2025

Related U.S. Application Data
(63) Continuation of application No. PCT/JP2024/022356, filed on Jun. 20, 2024.

(30) Foreign Application Priority Data
Jul. 3, 2023 (JP) 2023-109492

(51) Int. Cl. H01J 37/32; H10P 72/76

(52) U.S. Cl. CPC H01J 37/32724; H10P 72/7624; H01J 2237/334; H10P 72/7612

(57) ABSTRACT

A stage includes: a plate-shaped member having a mounting surface on which a substrate is to be placed and a rear surface opposite to the mounting surface, and having a through-hole penetrating the mounting surface and the rear surface, and an embedded member disposed in the through-hole, the embedded member includes a first member having a positive thermal expansion coefficient and a second member having a negative thermal expansion coefficient having an absolute value substantially equal to a thermal expansion coefficient of the first member along an axial direction of the embedded member.

### CROSS-REFERENCE TO RELATED APPLICATIONS

This application is a bypass continuation application of international application No. PCT/JP2024/022356 having an international filing date of Jun. 20, 2024, and designating the United States, the international application being based upon and claiming the benefit of priority from Japanese Patent Application No. 2023-109492, filed on Jul. 3, 2023, the entire contents of each are incorporated herein by reference.

### TECHNICAL FIELD

The present disclosure relates to a stage and a plasma processing apparatus.

### BACKGROUND

PTL 1 discloses a stage that includes an electrostatic chuck in which a first through-hole is formed, penetrating from a mounting surface on which a workpiece is to be placed to a rear surface located on an opposite side of the mounting surface, and pins accommodated in an inner wall of the first through-hole with a gap therebetween. The stage described in PTL 1 aims to prevent abnormal discharge in the first through-hole, which is, for example, a gas hole.

### CITATION LIST

### Patent Documents

PTL 1: JP2018-56372A

### SUMMARY

The technique according to the present disclosure appropriately reduces occurrence of abnormal discharge in a stage during plasma processing.

According to an aspect of the present disclosure, there is provided a stage on which a substrate is to be placed. The stage includes: a plate-shaped member having a mounting surface on which the substrate is to be placed and a rear surface opposite to the mounting surface, and having a through-hole penetrating the mounting surface and the rear surface, and an embedded member disposed in the through-hole. The embedded member includes a first member having a positive thermal expansion coefficient and a second member having a negative thermal expansion coefficient along an axial direction of the embedded member.

According to the present disclosure, it is possible to appropriately reduce the occurrence of abnormal discharge in the stage during the plasma processing.

### BRIEF DESCRIPTION OF DRAWINGS

FIG. 1 is a diagram schematically illustrating a configuration of a plasma processing system.

FIG. 2 is a cross-sectional view illustrating an example of a configuration of a plasma processing apparatus according to one or more embodiments.

FIG. 3 is a cross-sectional view illustrating an example of a configuration of a stage according to one or more embodiments.

FIG. 4 is an enlarged view of a main part in FIG. 3 illustrating an outline of a configuration of an embedded member.

FIG. 5 is a graph illustrating thermal properties of BNFO.

FIG. 6 is a graph illustrating a relationship between an amount of thermal deformation of a first member and a second member.

FIG. 7 is a diagram illustrating a positional relationship between the embedded member and a substrate.

FIG. 8 is a graph illustrating a discharge start voltage curve.

FIG. 9 is a cross-sectional view illustrating another example of the configuration of the embedded member.

### DETAILED DESCRIPTION

In a process of manufacturing a semiconductor device, various types of plasma processing such as an etching process, a film formation process, and a diffusion process are performed on a semiconductor substrate (hereinafter, simply referred to as “substrate”) on a stage by exciting a processing gas supplied into a chamber to generate a plasma. The stage on which the substrate is placed includes, for example, an electrostatic chuck that attracts and holds the substrate on a mounting surface by a Coulomb force or the like, and a base that supports the electrostatic chuck from below.

In the above-described stage, through-holes for supplying a heat transfer gas to, for example, a rear surface of the substrate or an edge ring on the mounting surface are formed. However, when the through-hole is formed inside the stage in this way, a potential difference occurs in a vertical direction of the through-hole (thickness direction of the stage) particularly during the plasma processing, which may cause abnormal discharge. When abnormal discharge occurs inside the through-hole, discharge marks are formed on the rear surface (holding surface) of the substrate on the stage, which may cause a problem in a later process.

PTL 1 discloses, as one method of reducing occurrence of abnormal discharge inside the stage (through-hole), disposing a pin inside the through-hole. According to the stage described in PTL 1, by disposing the pin in this way, an electric field space inside the through-hole becomes small, acceleration of ions entering from a plasma processing space is reduced, and occurrence of abnormal discharge can be reduced.

However, the present inventors have found that, particularly in a process in a low temperature region, the pin may thermally contract and a tip position of the pin may be lowered, which may expand the electric field space and make it impossible to properly reduce abnormal discharge inside the through-hole, i.e., there is room for improvement in a stage structure in the related art.

The present disclosure has been made in consideration of the above-described circumstances, and appropriately reduces occurrence of abnormal discharge in a stage during plasma processing. Hereinafter, a plasma processing system according to one or more embodiments will be described with reference to the drawings. The same reference numerals will be given to elements having substantially the same functional configurations throughout the specification, and redundant description thereof will be omitted.

### <Plasma Processing System>

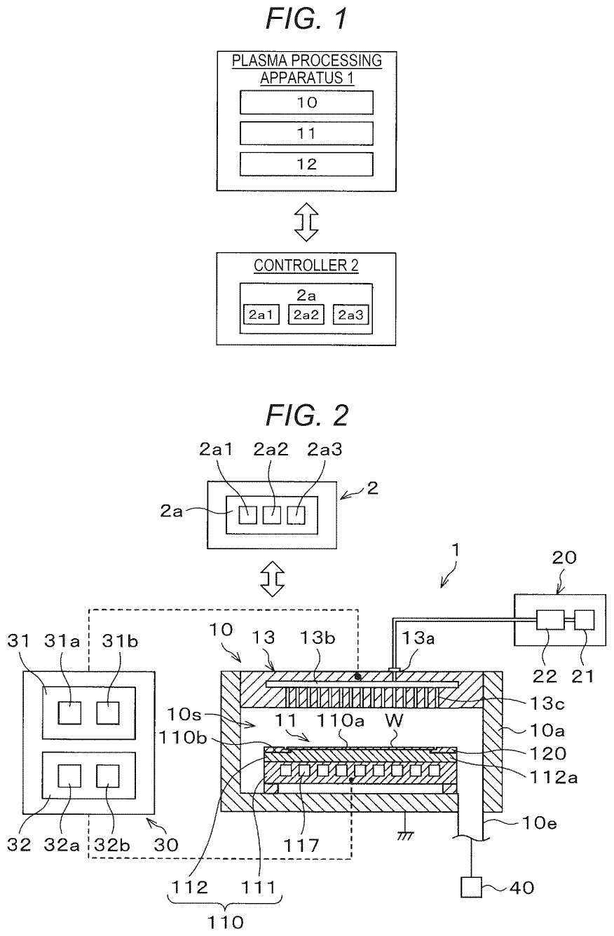

FIG. 1 is a diagram for explaining an example of a configuration of a plasma processing system. In one or more embodiments, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a stage 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The stage 11 is disposed in the plasma processing space and has a mounting surface on which a substrate is placed.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave-excited plasma (HWP), surface wave plasma (SWP), or the like. Further, various types of plasma generators, including an alternating current (AC) plasma generator and a direct current (DC) plasma generator, may be used. In one or more embodiments, an AC signal (AC power) used by the AC plasma generator has a frequency in a range of 100 kHz to 10 GHz. Accordingly, the AC signal includes a radio frequency (RF) signal and a microwave signal. In one or more embodiments, the RF signal has a frequency in a range of 100 kHz to 150 MHz.

The controller 2 processes computer-executable instructions for instructing the plasma processing apparatus 1 to execute various steps described herein below. The controller 2 may be configured to control elements of the plasma processing apparatus 1 to execute the various steps described herein below. In one or more embodiments, part or all of the controller 2 may be in the plasma processing apparatus 1. The controller 2 may include, for example, a computer 2a. For example, the computer 2a may include a processor (central processing unit (CPU)) 2al, a storage 2a2, and a communication interface 2a3. The processor 2al may be configured to read a program from the storage 2a2 and perform various control operations by executing the read program. The program may be stored in advance in the storage 2a2, or may be acquired via a medium when necessary. That is, the above storage 2a2 may be temporary or non-temporary. The acquired program is stored in the storage 2a2, read from the storage 2a2 by the processor 2al, and executed thereby. The medium may be various storing media readable by the computer 2a, or may be a communication line connected to the communication interface 2a3. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAS (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

### <Plasma Processing Apparatus>

Next, an example of a configuration of a capacitively-coupled plasma processing apparatus as an example of the plasma processing apparatus 1 will be described. FIG. 2 is a diagram illustrating the example of the configuration of the capacitively-coupled plasma processing apparatus.

The capacitively-coupled plasma processing apparatus 1 includes the plasma processing chamber 10, the gas supply 20, a power source 30, and the exhaust system 40. The plasma processing apparatus 1 includes the stage 11 and a gas introduction unit. The gas introduction unit is configured to introduce at least one processing gas into the plasma processing chamber 10. The gas introduction unit includes a shower head 13. The stage 11 is disposed in the plasma processing chamber 10. The shower head 13 is disposed above the stage 11. In one or more embodiments, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the stage 11. The plasma processing chamber 10 is grounded. The shower head 13 and the stage 11 are electrically insulated from a housing of the plasma processing chamber 10.

The stage 11 includes a main body 110, a ring assembly 120, and a lifter (not illustrated). The main body 110 has a central region 110a for supporting a substrate W and an annular region 110b for supporting the ring assembly 120. A wafer is an example of the substrate W. The annular region 110b of the main body 110 surrounds the central region 110a of the main body 110 in a plan view. The substrate W is disposed on the central region 110a of the main body 110, and the ring assembly 120 is disposed on the annular region 110b of the main body 110 to surround the substrate W on the central region 110a of the main body 110. Accordingly, the central region 110a is also called a mounting surface for supporting the substrate W or a substrate support surface, and the annular region 110b is also called a ring support surface that supports the ring assembly 120.

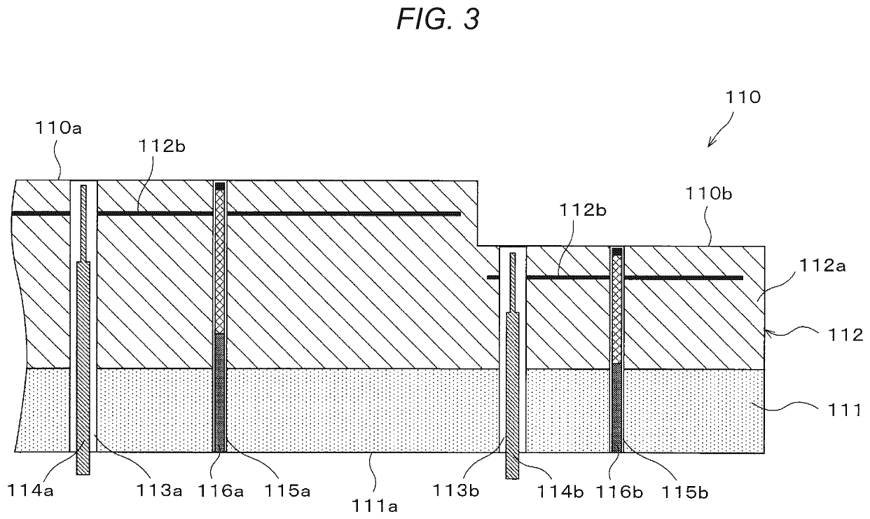

In one or more embodiments, the main body 110 of the stage 11 includes a base 111 and an electrostatic chuck 112 as illustrated in FIGS. 2 and 3. The base 111 includes a conductive member. The conductive member of the base 111 may function as a lower electrode. The electrostatic chuck 112 is disposed on the base 111. The electrostatic chuck 112 includes a ceramic member 112a and an electrostatic electrode 112b disposed in the ceramic member 112a. The ceramic member 112a has the central region 110a. In one or more embodiments, the ceramic member 112a also has the annular region 110b. The ceramic member 112a has a larger thickness in a portion corresponding to the central region 110a than in a portion corresponding to the annular region 110b. In other words, the ceramic member 112a has a substantially projecting cross-sectional shape in which the mounting surface (central region 110a) is higher than the ring support surface (annular region 110b) and a projecting portion is formed on an upper surface thereof, as illustrated in the drawing.

In the technique according to the present disclosure, the base 111 and the electrostatic chuck 112 together, that is, the main body 110 of the stage 11, may be referred to as a “plate-shaped member”.

Instead of the examples illustrated in FIGS. 2 and 3, another member that surrounds the electrostatic chuck 112, such as an annular electrostatic chuck or an annular insulating member, may have the annular region 110b. In this case, the ring assembly 120 may be disposed on the annular electrostatic chuck or the annular insulating member, or may be disposed on both the electrostatic chuck 112 and the annular insulating member. At least one RF/DC electrode coupled to an RF power source 31 and/or a DC power source 32, which will be described later, may be disposed in the ceramic member 112a. In this case, at least one RF/DC electrode functions as the lower electrode. When a bias RF signal and/or DC signal, which will be described later, is supplied to at least one RF/DC electrode, the RF/DC electrode is also referred to as a bias electrode. The conductive member of the base 111 and at least one RF/DC electrode may function as a plurality of lower electrodes. An electrostatic electrode 112b may also function as the lower electrode. Accordingly, the stage 11 includes at least one lower electrode.

The base 111 and the electrostatic chuck 112 have a plurality of first insertion holes 113a, or in one or more embodiments, three first insertion holes 113a, which penetrate from the mounting surface (central region 110a) to a rear surface 111a of the base 111 in the vertical direction (thickness direction). The rear surface 111a of the base 111 is a surface positioned on an opposite side of the mounting surface of the electrostatic chuck 112 on the stage 11.

A substrate lifter pin 114a is inserted into the first insertion hole 113a. The substrate lifter pin 114a is configured to protrude and retract from an upper surface of the mounting surface through the first insertion holes 113a, thereby supporting a lower surface of the substrate W placed on the mounting surface and moving (lifting up) the substrate W in the vertical direction. A plurality of first insertion holes 113a, or three in one or more embodiments, are formed corresponding to the number of the substrate lifter pins 114a.

The base 111 and the electrostatic chuck 112 have a plurality of second insertion holes 113b, or in one or more embodiments, three second insertion holes 113b, which penetrate from the ring support surface (annular region 110b) to the rear surface 111a of the base 111 in the vertical direction.

A ring lifter pin 114b is inserted into the second insertion hole 113b. The ring lifter pin 114b is configured to protrude and retract from an upper surface of the ring support surface through the second insertion hole 113b, thereby supporting a lower surface of the ring assembly 120 (described later) supported on the ring support surface and moving (lifting up) the ring assembly 120 in the vertical direction. A plurality of second insertion holes 113b, or three in one or more embodiments, are formed corresponding to the number of the ring lifter pins 114b.

In the base 111 and the electrostatic chuck 112, a plurality of first through-holes 115a for supplying a heat transfer gas (back-side gas: for example, a He gas) are formed between a rear surface of the substrate W and the central region 110a (mounting surface). The first through-hole 115a penetrates from the mounting surface (central region 110a) of the electrostatic chuck 112 to the rear surface 111a of the base 111 in the vertical direction (thickness direction). A plurality of (three in an example) first through-holes 115a are substantially uniformly disposed in a circumferential direction of the central region 110a (mounting surface). A heat transfer gas source (not illustrated) is connected to the first through-hole 115a.

An embedded member 116a is disposed in the first through-hole 115a to reduce occurrence of abnormal discharge in the first through-hole 115a during plasma processing in the plasma processing apparatus 1. A detailed configuration of the embedded member 116a will be described later.

Further, the base 111 and the electrostatic chuck 112 have a plurality of second through-holes 115b for supplying a heat transfer gas (back-side gas: for example, a He gas) between the ring assembly 120 and the annular region 110b (ring support surface). The second through-hole 115b penetrates from the ring support surface (annular region 110b) of the electrostatic chuck 112 to the rear surface 111a of the base 111 in the vertical direction (thickness direction). A plurality of (in an example, three) second through-holes 115b are substantially uniformly disposed in the circumferential direction of the annular region 110b (ring support surface). A heat transfer gas source (not illustrated) is connected to the second through-hole 115b.

An embedded member 116b is disposed in the second through-hole 115b to reduce occurrence of abnormal discharge in the second through-hole 115b during plasma processing in the plasma processing apparatus 1. A detailed configuration of the embedded member 116b will be described later.

The ring assembly 120 includes one or a plurality of annular members. In one or more embodiments, the one or more annular members include one or more edge rings and at least one cover ring. The edge ring is made of an electrically conductive material or an insulating material, and the cover ring is made of an insulating material.

The stage 11 may include a temperature control module configured to adjust at least one of the electrostatic chuck 112, the ring assembly 120, and the substrate W to a target temperature. The temperature control module may include a heater, a heat transfer medium, a flow path 117, or a combination thereof. A heat transfer fluid, such as brine or a gas, flows through the flow path 117. In one or more embodiments, the flow path 117 is formed in the base 111, and one or a plurality of heaters are disposed in the ceramic member 112a of the electrostatic chuck 112. To prevent complexity of the illustration, the illustration of the flow path 117 is omitted in FIG. 3.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The shower head 13 further includes at least one upper electrode. The gas introduction section may include, in addition to the shower head 13, one or more side gas injectors (SGIs) attached to one or more openings formed in the sidewall 10a.

The gas supply 20 may include at least one gas source 21 and at least one flow rate controller 22. In one or more embodiments, the gas supply 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. The gas supply 20 may further include at least one flow rate modulating device that modulates or pulses the flow rate of the at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Plasma is thus formed from the at least one processing gas supplied into the plasma processing space 10s. Accordingly, the RF power source 31 may function as at least a part of the plasma generator 12. Furthermore, supplying the bias RF signal to the at least one lower electrode can generate a bias potential at the substrate W to attract the ionic component in the formed plasma to the substrate W.

In one or more embodiments, the RF power source 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one or more embodiments, the source RF signal has a frequency within a range from 10 MHz to 150 MHz. In one or more embodiments, the first RF generator 31a may be configured to generate a plurality of source RF signals having different frequencies. The generated one or more source RF signals are supplied to the at least one lower electrode and/or the at least one upper electrode.

The second RF generator 31b is coupled to at least one lower electrode via at least one impedance matching circuit and configured to generate the bias RF signal (bias RF power). A frequency of the bias RF signal may be the same as or different from a frequency of the source RF signal. In one or more embodiments, the bias RF signal has a frequency lower than the frequency of the source RF signal. In one or more embodiments, the bias RF signal has a frequency within a range from 100 kHz to 60 MHz. In one or more embodiments, the second RF generator 31b may be configured to generate a plurality of bias RF signals having different frequencies. The generated one or more bias RF signals are supplied to the at least one lower electrode. Furthermore, in various embodiments, at least one of the source RF signal and the bias RF signal may be pulsed.

The power source 30 may include the DC power source 32 coupled to the plasma processing chamber 10. The DC power source 32 includes a first DC generator 32a and a second DC generator 32b. In one or more embodiments, the first DC generator 32a is connected to at least one lower electrode to generate a first DC signal. The generated first DC signal is applied to the at least one lower electrode. In one or more embodiments, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one or more embodiments, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected, for example, to a gas discharge port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

### Embedded Member

As described above, in the stage in the related art disclosed in, for example, PTL 1, a pin member disposed inside the through-hole (corresponding to the embedded member 116 in one or more embodiments) contracts due to a process temperature, so that the electric field space (more specifically, a distance between a rear surface of a substrate and a tip of the pin member) widens, which causes occurrence of abnormal discharge.

Therefore, in the stage 11 according to the present invention, the embedded members 116a and 116b are disposed inside the first and second through-holes 115a and 115b, so that occurrence of abnormal discharge in the first and second through-holes 115a and 115b is reduced.

Hereinafter, the detailed configurations of the embedded members 116a and 116b disposed in the first and second through-holes 115a and 115b will be described. Since each of the embedded members 116a and 116b has a similar configuration, in the following description, the first through-hole 115a and the second through-hole 115b may be collectively referred to simply as “through-hole 115”, and similarly, the embedded members 116a and 116b may be collectively referred to simply as “embedded member 116”.

In other words, the “through-hole 115” in the following description represents at least one of the first through-hole 115a and the second through-hole 115b, and the “embedded member 116” represents at least one of the embedded members 116a and 116b.

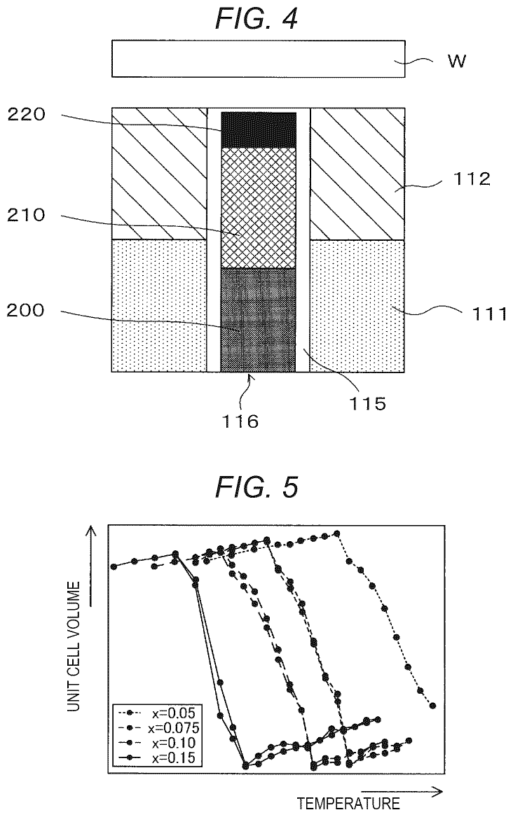

As illustrated in FIG. 4, the embedded member 116 has a substantially pin shape extending in a direction in which the through-hole 115 is formed (the thickness direction of the stage 11). A gap is formed between the embedded member 116 and an inner wall of the through-hole 115, and the above-described heat transfer gas is supplied between the substrate W and the central region 110a or between the ring assembly 120 and the annular region 110b through the gap.

As illustrated in FIG. 4, the embedded member 116 has a configuration in which a first member 200, a second member 210, and a third member 220 are connected in order along the axial direction of the embedded member 116 from a base side (the rear surface 111a of the stage 11) toward a tip side (the mounting surface of the stage 11).

As the first member 200, a member having a positive thermal expansion coefficient, i.e., a member that expands during a high-temperature process and contracts during a low-temperature process is selected. Specifically, as the first member 200, in the related art, a material used as a constituent member for the through-hole 115, such as Poly Tetra Fluoro Ethylene (PTFE) or metal, can be selected.

As the second member 210, a member having a negative thermal expansion coefficient, i.e., a member that contracts during a high-temperature process and expands during a low-temperature process is selected. Specifically, as the second member 210, a material having an absolute value of a thermal expansion coefficient close to, or preferably equal to, an absolute value of a thermal expansion coefficient of the member (for example, PTFE) that constitutes the first member 200, for example, bismuth nickel iron oxide (BNFO) can be selected.

The BNFO, which can be selected as the second member 210 having the negative thermal expansion coefficient, is represented by a chemical formula [BiNi_{1-X}Fe_{X}O₃]. FIG. 5 illustrates a unit cell volume of BNFO versus temperature. In the drawing, X is X in the chemical formula and represents a ratio of nickel (Ni) to iron (Fe). As illustrated in FIG. 5, the BNFO has a region that exhibits negative thermal expansion coefficient characteristics depending on temperature bands. This region shifts according to the ratio of nickel to iron. In other words, by using these characteristics, the thermal expansion coefficient of the second member 210 can be approximated to the thermal expansion coefficient of the first member 200 according to a temperature of a process for the substrate W and the ratio of nickel to iron, and thus can be suitably applied as the second member 210.

The third member 220 is a member disposed at a tip portion of the embedded member 116, that is, nearest to the plasma processing space 10s, and prevents the first member 200 and the second member 210 from being worn away by a plasma during a process or during wafer less dry cleaning (WLDC) and prevents a height (tip position) of the embedded member 116 from being lowered. As the third member 220, a material having plasma resistance, for example, SiC, silicon, or ceramic can be selected.

The third member 220 may be appropriately omitted depending on a process condition and a purpose for the substrate W. In other words, in the technique according to the present disclosure, the embedded member 116 includes at least the first member 200 and the second member 210.

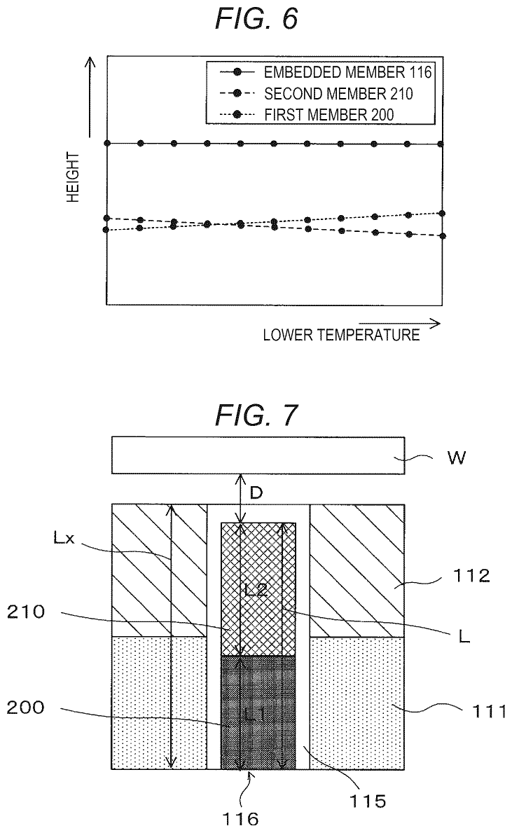

In the embedded member 116 according to the technique of the present disclosure, the first member 200 having the positive thermal expansion coefficient and the second member 210 having the negative thermal expansion coefficient are disposed in combination in the axial direction. At this time, the first member 200 and the second member 210 are selected such that absolute values of their respective thermal expansion coefficients are approximate to each other, and preferably coincide with each other. Accordingly, as illustrated in FIG. 6, a thermal expansion amount and a thermal contraction amount that occur in the embedded member 116 are approximate to or coincide with each other, i.e., deformation that occurs in the axial direction of the first member 200 and the second member 210 cancels each other, and a length of the embedded member 116 can be maintained constant regardless of the process temperature for the substrate W. In other words, the tip position of the embedded member 116 is prevented from fluctuating, and thus a distance between the rear surface of the substrate W and a tip of the embedded member 116 is maintained to be constant, so that occurrence of the abnormal discharge in the through-hole 115 is prevented.

In one or more embodiments, the absolute values of the thermal expansion coefficients of the first member 200 and the second member 210 being “close” preferably means that a ratio of the absolute values of the thermal expansion coefficients is 0.8 or more and 1.2 or less, more preferably 0.85 or more and 1.15 or less.

More specifically, an amount of change ΔL in a length L (see FIG. 7) of the embedded member 116 in the axial direction due to a temperature change can be obtained by formula (1) below. At this time, the absolute values of the thermal expansion coefficients of the first member 200 and the second member 210 are “close” to each other when a distance D (see FIG. 7) between the substrate W and the tip portion of the embedded member 116, which varies depending on the amount of change ΔL, satisfies formula (4) below.

ΔL=ΔL1+ΔL2={(α1aL1(0))+(α2aL2(0))}×(T−T0) (1)

In the above formula (1), ΔL1 represents an amount of change of a length of the first member 200 in the axial direction (thermal expansion amount), ΔL2 represents an amount of change of a length of the second member 210 in the axial direction (thermal contraction amount), a represents the thermal expansion coefficient, L1(0) represents an initial length (of the first member 200), L2(0) represents an initial length (of the second member 210), T represents the process temperature, and TO represents an initial temperature, respectively.

As described later, when the first member 200 and/or the second member 210 are made of a plurality of materials (constituted by a plurality of layers), the product [α1aL1(0)] of the thermal expansion coefficient α and the initial length L0 in the above formula (1) may be replaced with a total sum [α1d1+α2d2+ . . . ] of the products of the thermal expansion coefficients α and thicknesses of the materials.

The distance D between the substrate W and the tip portion of the embedded member 116 that varies according to formula (1) above can be calculated based on formulas (2) and (3) below.

D=D0+AD=D0+ΔLx−ΔL (2)

ΔLx=(αxadxa+αxbdxb+ . . . )×(T−T0) (3)

In formula (2), DO represents an initial distance (before a process) between the substrate W and the tip portion of the embedded member 116, and ΔLx represents an amount of change in a thickness of the stage 11.

That is, since the distance D between the substrate W and the tip portion of the embedded member 116 is also affected by a thickness change of the stage 11 (the base 111 and the electrostatic chuck 112), such thermal deformation (thermal expansion/contraction) of the stage 11 is considered. In other words, at least one of the material (thermal expansion coefficient α) and the thickness d of the first member 200 and/or the second member 210 is preferably determined in consideration of the thermal deformation of the stage 11.

At this time, the distance D obtained by formulas (2) and (3) above needs to satisfy formula (4) below.

0<D<D MAX (4)

When the distance D becomes 0, the tip of the embedded member 116 comes into contact with the rear surface of the substrate W, so that the rear surface of the substrate W may be damaged, which may cause a problem or particle generation in a subsequent process.

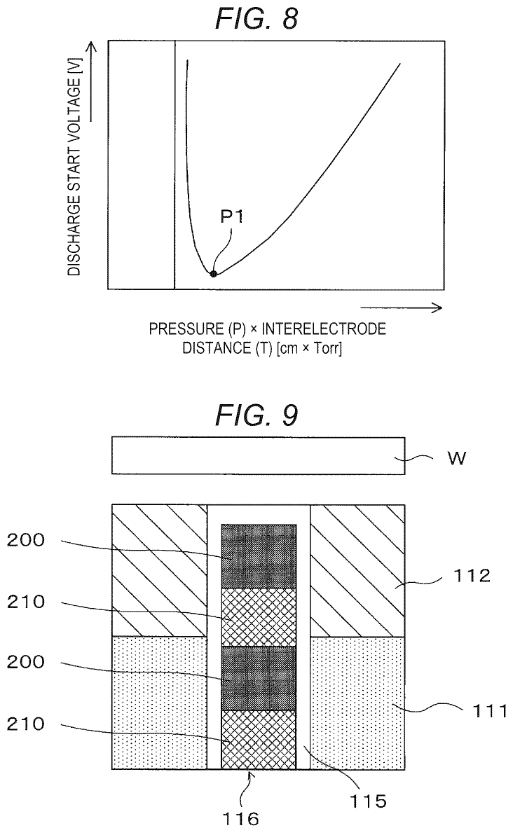

Meanwhile, DMAX as a condition satisfied by the distance D is a maximum value of the distance between the rear surface of the substrate W and the tip of the embedded member 116 at which no abnormal discharge occurs in an electric field space, and is set under a condition that a discharge start voltage becomes at least smaller than a minimum value P1 (a condition under which discharge is most likely to occur) obtained from a discharge start voltage curve according to Paschen's law (see FIG. 8).

Due to design tolerances of the first member 200, the second member 210, and the stage 11 (the base 111 and the electrostatic chuck 112), even if formula (4) is satisfied in calculation, an actual range may be exceeded. Therefore, it is desirable to consider the tolerance. Specifically, by designing the range to be satisfied by the distance D to be narrower than that in formula (4) above in consideration of tolerances, it is possible to more appropriately prevent the distance D from deviating from a range of formula (4) above, for example, prevent the rear surface of the substrate W from coming into contact with the tip of the embedded member 116.

According to the technique of the present disclosure, the first member 200 and the second member 210 whose absolute values of the thermal expansion coefficients are close to or coincide with each other are disposed in combination, and the distance D between the substrate W and the tip portion of the embedded member 116 is maintained to be larger than 0 and smaller than the DMAX regardless of the process temperature for the substrate W, so that occurrence of abnormal discharge in the through-hole 115 can be appropriately reduced.

In the embodiment described above, the first member 200 having the positive thermal expansion coefficient and the second member 210 having the negative thermal expansion coefficient are connected in this order from the base side of the embedded member 116. However, the second member 210 may be disposed on the base side of the embedded member 116 and the first member 200 may be disposed on the tip side of the embedded member 116.

In the embodiment described above, the first member 200 and the second member 210 are disposed in one layer each in the axial direction of the embedded member 116. However, as illustrated in FIG. 9, the first member 200 and the second member 210 may be disposed in two or more layers in the axial direction of the embedded member 116. In other words, disposition of the first member 200 and the second member 210 is not particularly limited, as long as the thermal expansion coefficient of the entire embedded member 116 can be balanced and the length of the embedded member 116 can be maintained constant regardless of the process temperature.

At this time, each of the plurality of first members 200 to be stacked does not need to be made of the same material, and different materials having a positive thermal expansion coefficient may be combined and disposed. Similarly, each of the plurality of second members 210 to be stacked does not need to be made of the same material.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above.

For example, in the above-described embodiment, the case where the embedded member 116 for preventing the occurrence of the abnormal discharge in the plasma processing apparatus 1 is disposed in the through-hole 115 for supplying the heat transfer gas in the stage 11 has been described by way of example.

However, an application position of the embedded member 116 described above is not limited thereto, and for example, the embedded member 116 may be applied to the first insertion hole 113a and/or the second insertion hole 113b through which the substrate lifter pin 114a for raising and lowering the substrate W on the stage 11 and the ring lifter pin 114b for raising and lowering the ring assembly 120 are inserted.

For example, a structure of the embedded member 116 described above may be applied to positioning pins (not illustrated) for positioning the ring assembly 120 on the stage 11. That is, the above-described structure may be applied to the positioning pin inserted into a positioning hole (not illustrated) formed in a rear surface of the ring assembly 120, and a distance between the rear surface of the ring assembly 120 and a tip portion of the positioning pin may be maintained to be constant regardless of the process temperature.

Similarly, the structure of the embedded member 116 described above may be applied to a positioning pin (not illustrated) of the upper electrode (shower head 13 in the embodiment described above) of the plasma processing apparatus 1 with respect to the plasma processing chamber 10. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

The following configuration examples also fall within the technical scope of the present disclosure.

(1) A stage includes: a plate-shaped member having a mounting surface on which a substrate is to be placed and a rear surface opposite to the mounting surface, and having a through-hole penetrating the mounting surface and the rear surface, and an embedded member disposed in the through-hole, in which the embedded member includes a first member having a positive thermal expansion coefficient and a second member having a negative thermal expansion coefficient along an axial direction of the embedded member.

(2) The stage according to (1), in which a ratio of an absolute value of the thermal expansion coefficient of the first member and an absolute value of the thermal expansion coefficient of the second member is 0.8 or more and 1.2 or less, and more preferably 0.85 or more and 1.15 or less.

(3) The stage according to (1) or (2), in which the first member and/or the second member are determined based on a thermal expansion coefficient of the plate-shaped member.

(4) The stage according to any one of (1) to (3), in which the embedded member includes a plurality of the first members along the axial direction of the embedded member.

(5) The stage according to any one of (1) to (4), in which the embedded member includes a plurality of the second members along the axial direction of the embedded member.

(6) The stage according to any one of (1) to (5), in which the embedded member includes a third member having plasma resistance at a tip of the embedded member.

(7) The stage according to any one of (1) to (6), in which a gap is formed between the embedded member and the through-hole.

(8) A plasma processing apparatus for processing a substrate, the plasma processing apparatus includes: a plasma processing chamber, a plasma generator, and a stage disposed in the plasma processing chamber, in which the stage includes a plate-shaped member having a mounting surface on which the substrate is to be placed and a rear surface opposite to the mounting surface, and having a through-hole penetrating the mounting surface and the rear surface, and an embedded member disposed in the through-hole and including a first member having a positive thermal expansion coefficient and a second member having a negative thermal expansion coefficient along an axial direction of the embedded member.

(9) The plasma processing apparatus according to (8), in which a ratio of an absolute value of the thermal expansion coefficient of the first member and an absolute value of the thermal expansion coefficient of the second member is 0.8 or more and 1.2 or less, and more preferably 0.85 or more and 1.15 or less.

(10) The plasma processing apparatus according to (8) or (9), in which the first member and/or the second member are determined based on a thermal expansion coefficient of the plate-shaped member.

(11) The plasma processing apparatus according to any one of (8) to (10), in which the embedded member includes a plurality of the first members along the axial direction of the embedded member.

(12) The plasma processing apparatus according to any one of (8) to (11), in which the embedded member includes a plurality of the second members along the axial direction of the embedded member.

(13) The plasma processing apparatus according to any one of (8) to (12), in which the embedded member includes a third member having plasma resistance at a tip of the embedded member.

(14) The plasma processing apparatus according to any one of (8) to (13), in which a gap is formed between the embedded member and the through-hole.

(15) A method for plasma processing a substrate, comprising:
providing a stage comprising:
   a plate-shaped member including:
      a mounting surface on which a substrate is to be placed;
      a rear surface opposite to the mounting surface; and
      a through-hole penetrating the mounting surface and the rear surface,
   and
   an embedded member disposed in the through-hole and including a first member having a positive thermal expansion coefficient and a second member having a negative thermal expansion coefficient along an axial direction of the embedded member;
placing the substrate on the mounting surface;
supplying a processing gas into a plasma processing chamber in which the stage is disposed;
generating plasma from the processing gas; and
etching the substrate with the plasma while supplying a heat transfer gas through the through-hole via a gap formed between the embedded member and the through-hole to maintain substrate temperature.

(16) The method according to (15), wherein the first member comprises poly tetrafluoroethylene and the second member comprises bismuth nickel iron oxide.

(17) The method according to (15), wherein the third member comprises silicon carbide.

(18) The stage according to (1), wherein the first member comprises poly tetrafluoroethylene.

(19). The stage according to (1), wherein the second member comprises bismuth nickel iron oxide.

(20) The stage according to (1), wherein the gap supplies a helium heat transfer gas therethrough.

1. A stage comprising:
a plate-shaped member including:
a mounting surface on which a substrate is to be placed;
a rear surface opposite to the mounting surface; and
a through-hole penetrating the mounting surface and the rear surface, and
an embedded member disposed in the through-hole and including
a first member having a positive thermal expansion coefficient and a second member having a negative thermal expansion coefficient along an axial direction of the embedded member.

2. The stage according to claim 1, wherein
a ratio of an absolute value of the thermal expansion coefficient of the first member and an absolute value of the thermal expansion coefficient of the second member is 00.85 or more and 1.15 or less.

3. The stage according to claim 1, wherein
the first member and/or the second member are determined based on a thermal expansion coefficient of the plate-shaped member.

4. The stage according to claim 1, wherein
the embedded member includes a plurality of the first members along the axial direction of the embedded member.

5. The stage according to claim 1, wherein
the embedded member includes a plurality of the second members along the axial direction of the embedded member.

6. The stage according to claim 1, wherein
the embedded member includes a third member having plasma resistance at a tip of the embedded member.

7. The stage according to claim 1, wherein
a gap is formed between the embedded member and the through-hole.

8. A plasma processing apparatus for processing a substrate, the plasma processing apparatus comprising:
a plasma processing chamber,
a plasma generator, and
a stage disposed in the plasma processing chamber, the stage including
a plate-shaped member including:
a mounting surface on which the substrate is to be placed;
a rear surface opposite to the mounting surface; and
a through-hole penetrating the mounting surface and the rear surface; and
an embedded member disposed in the through-hole and including a first member having a positive thermal expansion coefficient and a second member having a negative thermal expansion coefficient along an axial direction of the embedded member.

9. The plasma processing apparatus according to claim 8, wherein
a ratio of an absolute value of the thermal expansion coefficient of the first member and an absolute value of the thermal expansion coefficient of the second member is 0.85 or more and 1.15 or less.

10. The plasma processing apparatus according to claim 8, wherein
the first member and/or the second member are determined based on a thermal expansion coefficient of the plate-shaped member.

11. The plasma processing apparatus according to claim 8, wherein
the embedded member includes a plurality of the first members along the axial direction of the embedded member.

12. The plasma processing apparatus according to claim 8, wherein
the embedded member includes a plurality of the second members along the axial direction of the embedded member.

13. The plasma processing apparatus according to claim 8, wherein
the embedded member includes a third member at a tip of the embedded member, the third member comprising SiC, silicon, or ceramic.

14. The plasma processing apparatus according to claim 8, wherein
a gap is formed between the embedded member and the through-hole.

15. A method for plasma processing a substrate, comprising:
providing a stage comprising:
a plate-shaped member including:
a mounting surface on which a substrate is to be placed;
a rear surface opposite to the mounting surface; and
a through-hole penetrating the mounting surface and the rear surface, and
an embedded member disposed in the through-hole and including a first member having a positive thermal expansion coefficient and a second member having a negative thermal expansion coefficient along an axial direction of the embedded member;
placing the substrate on the mounting surface;
supplying a processing gas into a plasma processing chamber in which the stage is disposed;
generating plasma from the processing gas; and
etching the substrate with the plasma while supplying a heat transfer gas through the through-hole via a gap formed between the embedded member and the through-hole to maintain substrate temperature.

16. The method according to claim 15, wherein the first member comprises poly tetrafluoroethylene and the second member comprises bismuth nickel iron oxide.

17. The method according to claim 15, wherein the third member comprises silicon carbide.

18. The stage according to claim 1, wherein the first member comprises poly tetrafluoroethylene.

19. The stage according to claim 1, wherein the second member comprises bismuth nickel iron oxide.

20. The stage according to claim 1, wherein the gap supplies a helium heat transfer gas therethrough.
